(19) United States
(12) Patent Application Publication
(10) Pub. No.: US 2016/0380115 A1
(43) Pub. Date: Dec. 29, 2016

(54) THIN FILM TRANSISTOR, SEMICONDUCTOR DEVICE, AND METHOD FOR MANUFACTURING THIN FILM TRANSISTOR

(71) Applicant: Kabushiki Kaisha Toshiba, Minato-ku (JP)

(72) Inventors: Shintaro NAKANO, Kawasaki (JP); Yuya MAEDA, Kawasaki (JP); Tatsuya OHGURO, Yokohama (JP); Hisayo MOMOSE, Yokohama (JP); Tetsu MOROOKA, Yokohama (JP); Kazuya FUKASE, Hachioji (JP); Nobuki KANREI, Yokohama (JP)

(73) Assignee: Kabushiki Kaisha Toshiba, Minato-ku (JP)

(21) Appl. No.: 15/258,233

(22) Filed: Sep. 7, 2016

Related U.S. Application Data
(63) Continuation of application No. PCT/JP2014/082027, filed on Dec. 3, 2014.

(30) Foreign Application Priority Data
Mar. 31, 2014 (JP) 2014-073679

(51) Int. Cl. H01L 29/786; H01L 21/4757; H01L 21/465; H01L 23/522; H01L 29/66

(52) U.S. Cl. CPC H01L 29/78696; H01L 29/78648; H01L 29/7869; H01L 23/5226; H01L 29/66969; H01L 21/465; H01L 21/47573

(57) ABSTRACT

A thin film transistor includes semiconductor layer, source electrode, and drain electrode. The semiconductor layer includes first to fifth regions. The third region is provided between the first and second regions. The first region is disposed between the fourth and third regions. The second region is disposed between the fifth and third regions. The semiconductor layer includes an oxide. The source electrode is connected to the first region. The drain electrode is connected to the second region. First thickness of the first region along a second direction is thinner than third thickness along the second direction of each of the third to fifth regions. The second direction crosses a first direction and connects the first region and the source electrode. The first direction connects the first and second regions. Second thickness of the second region along the second direction is thinner than the third thickness.

### CROSS-REFERENCE TO RELATED APPLICATIONS

This is a continuation application of International Application PCT/JP2014/082027, filed on Dec. 3, 2014; the entire contents of which are incorporated herein by reference.

### FIELD

Embodiments described herein relate generally to a thin film transistor, a semiconductor device, and a method for manufacturing thin film transistor.

### BACKGROUND

A thin film transistor that uses an oxide semiconductor is used in a liquid crystal display device, an organic electroluminescence (EL) display device, etc. It is desirable for the thin film transistor to be stable.

### BRIEF DESCRIPTION OF THE DRAWINGS

FIG. 1 is a schematic cross-sectional view illustrating a thin film transistor according to a first embodiment;

FIG. 2 is a flowchart illustrating a method for manufacturing the thin film transistor according to the first embodiment;

FIGS. 3A to 3F are schematic cross-sectional views in order of the processes, illustrating the method for manufacturing the thin film transistor according to the first embodiment;

FIG. 4 is a top view of the thin film transistor according to the first embodiment;

FIG. 5 is a schematic cross-sectional view illustrating a thin film transistor according to a second embodiment;

FIG. 6 is a flowchart illustrating a method for manufacturing the thin film transistor according to the second embodiment;

FIGS. 7A to 7G are schematic cross-sectional views in order of the processes, illustrating the method for manufacturing the thin film transistor according to the second embodiment;

FIG. 8 is a top view of the thin film transistor according to the second embodiment;

FIG. 9 is a schematic cross-sectional view illustrating a thin film transistor according to a third embodiment;

FIG. 10 is a flowchart illustrating a method for manufacturing the thin film transistor according to the third embodiment;

FIGS. 11A to 11F are schematic cross-sectional views in order of the processes, illustrating the method for manufacturing the thin film transistor according to the third embodiment;

FIG. 12 is a top view of the thin film transistor according to the third embodiment;

FIG. 13 is a schematic cross-sectional view illustrating a display device according to a fourth embodiment;

FIG. 14 is a schematic view illustrating a semiconductor device according to a fifth embodiment; and

FIG. 15 is a schematic view showing another semiconductor device according to the fifth embodiment.

### DETAILED DESCRIPTION

According to one embodiment, a thin film transistor includes a semiconductor layer, a source electrode, and a drain electrode. The semiconductor layer includes a first region, a second region, a third region, a fourth region, and a fifth region.

The third region is provided between the first region and the second region. The first region is disposed between the fourth region and the third region. The second region is disposed between the fifth region and the third region. The semiconductor layer includes an oxide. The source electrode is electrically connected to the first region. The drain electrode is electrically connected to the second region. A first thickness of the first region along a second direction is thinner than a third thickness along the second direction of each of the third region, the fourth region, and the fifth region. The second direction crosses a first direction and connects the first region and the source electrode. The first direction connects the first region and the second region. A second thickness of the second region along the second direction is thinner than the third thickness.

According to another embodiment, a semiconductor device includes a semiconductor circuit, an interconnect layer, and a thin film transistor. The interconnect layer includes an interconnect. The interconnect is connected to the semiconductor circuit. The thin film transistor includes a semiconductor layer, a source electrode, and a drain electrode.

The semiconductor layer includes a first region, a second region, a third region, a fourth region, and a fifth region. The third region is provided between the first region and the second region. The first region is disposed between the fourth region and the third region. The second region is disposed between the fifth region and the third region. The semiconductor layer includes an oxide. The source electrode is electrically connected to the first region. The drain electrode is electrically connected to the second region. A first thickness of the first region along a second direction is thinner than a third thickness along the second direction of each of the third region, the fourth region, and the fifth region. The second direction crosses a first direction and connects the first region and the source electrode. The first direction connects the first region and the second region. A second thickness of the second region along the second direction is thinner than the third thickness. The thin film transistor is provided inside the interconnect layer.

According to another embodiment, a method is disclosed for manufacturing a thin film transistor. The method can include forming a semiconductor film including a first portion and a second portion. The second portion is separated from the first portion. The semiconductor film includes an oxide. The method can include forming an inter-layer insulating film on the semiconductor film. The method can include forming a first opening and a second opening in the inter-layer insulating film by dry etching. The first opening reaches the first portion. The second opening reaches the second portion. The method can include removing a first removed portion via the first opening and a second removed portion via the second opening by wet etching. The first removed portion is a portion of the first portion. The second removed portion is a portion of the second portion. The method can include connecting a source electrode to a first region remaining where the first removed portion is removed, and connecting a drain electrode to a second region remaining where the second removed portion is removed.

Various embodiments will be described hereinafter with reference to the accompanying drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In the present specification and the drawings, components similar to those described previously with reference to earlier figures are labeled with like reference numerals, and the detailed description thereof is omitted appropriately.

### First Embodiment

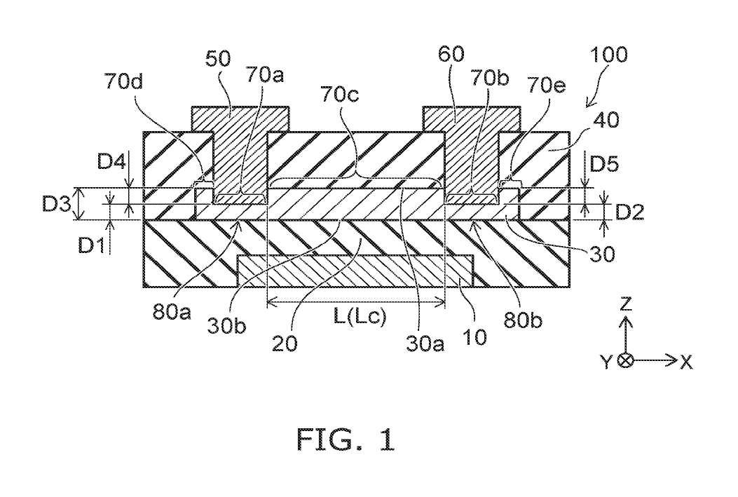

FIG. 1 is a schematic cross-sectional view illustrating a thin film transistor according to a first embodiment.

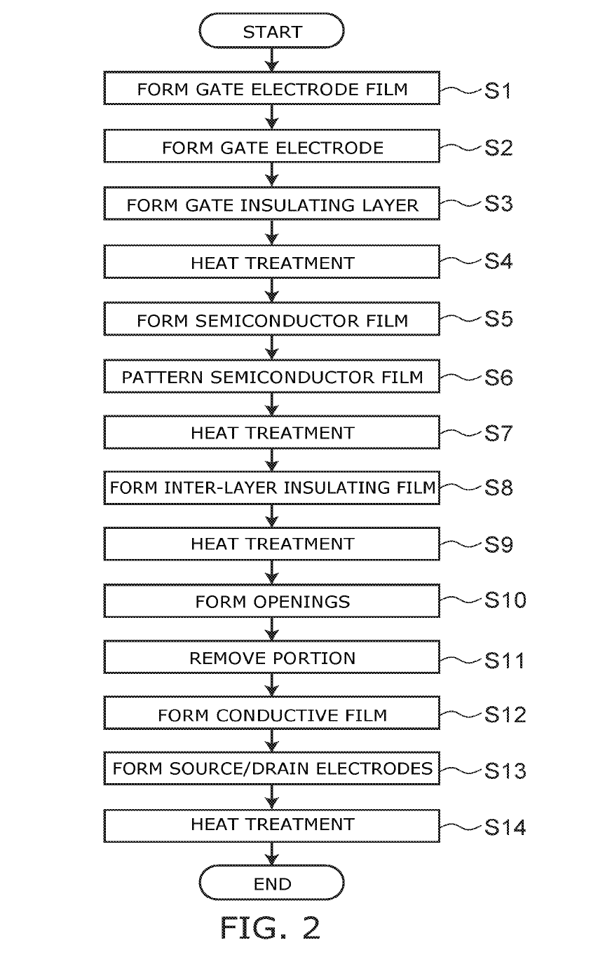

FIG. 2 is a flowchart illustrating a method for manufacturing the thin film transistor according to the first embodiment.

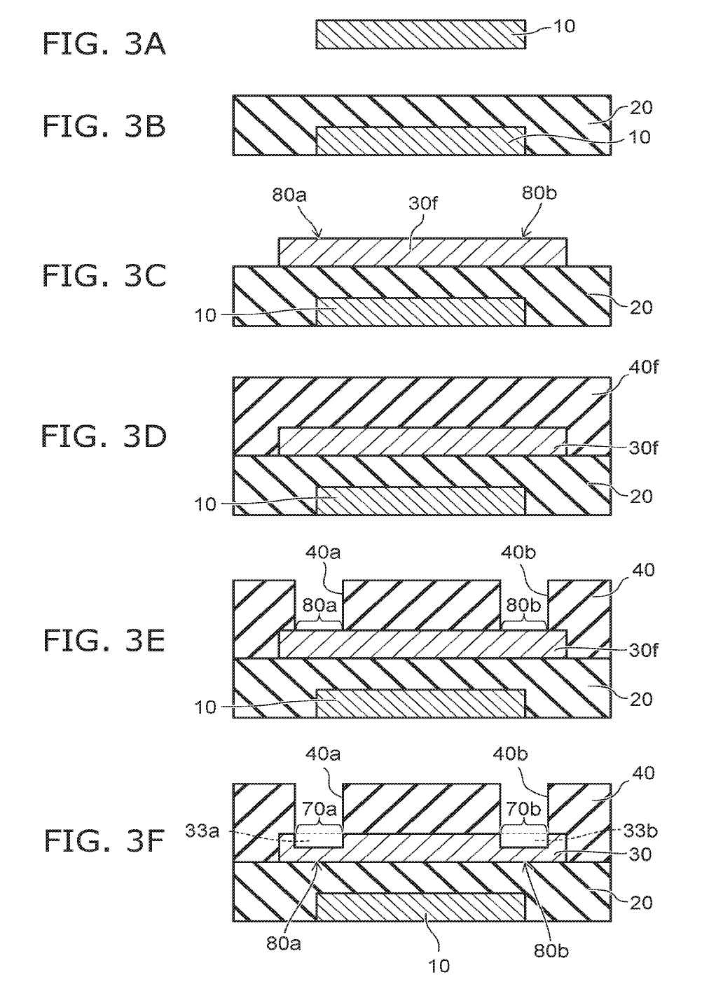

FIG. 3A to FIG. 3F are schematic cross-sectional views in order of the processes, illustrating the method for manufacturing the thin film transistor according to the first embodiment.

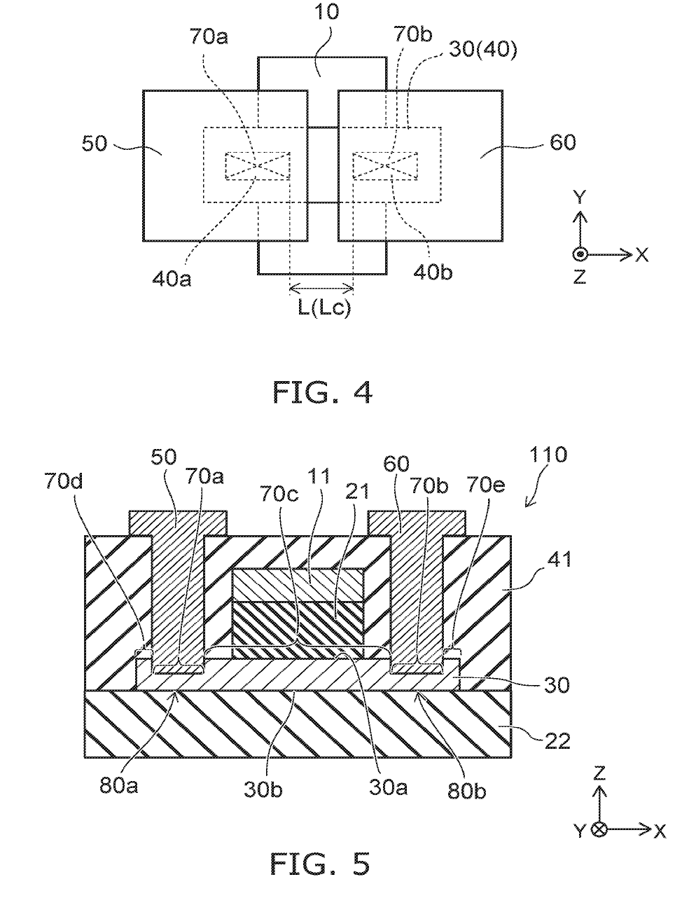

FIG. 4 is a top view of the thin film transistor according to the first embodiment.

An example of the structure of the thin film transistor 100 having a bottom-gate structure and a method for manufacturing the thin film transistor 100 are described in the embodiment.

As shown in FIG. 1, the thin film transistor 100 according to the embodiment includes a gate electrode 10, a gate insulating layer 20, a semiconductor layer 30, an inter-layer insulating layer 40 (called, for example, an etching stopper layer), a source electrode 50, and a drain electrode 60.

In the example, a direction from the semiconductor layer 30 toward the source electrode 50 is taken as a Z-axis direction. One direction perpendicular to the Z-axis direction is taken as an X-axis direction. A direction perpendicular to the Z-axis direction and the X-axis direction is taken as the Y-axis direction.

The semiconductor layer 30 includes an oxide of at least one of In, Ga, or Zn. For example, InGaZnO is included in the semiconductor layer 30. The semiconductor layer 30 may include N and at least one of In, Ga, or Zn. The semiconductor layer 30 may include InGaZnO: N. The semiconductor layer 30 may include InZnO. The semiconductor layer 30 may include InGaO. The semiconductor layer 30 may include InSnZnO. The semiconductor layer 30 may include InSnGaZnO. The semiconductor layer 30 may include InSnO.

The gate electrode 10 includes, for example, at least one of W, Mo, Ta, TaN, Ti, TiN, Al, AlNd, Cu, ITO, or IZO. The gate electrode 10 may include an alloy of these materials or a stacked structure of films of these materials.

The gate insulating layer 20 includes, for example, at least one of silicon oxide, silicon nitride, silicon oxynitride, TEOS (Tetra Eth OxySilane), aluminum oxide, tantalum oxide, hafnium oxide, zirconium oxide, or titanium oxide. The gate insulating layer 20 may include a mixture of these materials or a stacked structure of films of these materials.

The etching stopper layer 40 includes, for example, at least one of silicon oxide, silicon nitride, silicon oxynitride, TEOS, aluminum oxide, tantalum oxide, hafnium oxide, zirconium oxide, or titanium oxide. The etching stopper layer 40 may include a mixture of these materials or a stacked structure of films of these materials. Silicon oxide and aluminum oxide are more favorable.

The source electrode 50 and the drain electrode 60 include, for example, at least one of Ti, Mo, Al, Cu, Ta, W, TiN, TaN, MoN, ITO, IZO, InGaZn, or InGaZnO:N. The source electrode 50 and the drain electrode 60 may include an alloy of these materials or a stacked structure of films of these materials.

In FIG. 1, the semiconductor layer 30 includes a first region 70a, a second region 70b, a third region 70c, a fourth region 70d, and a fifth region 70e. The third region 70c is provided between the first region 70a and the second region 70b. The first region 70a is provided between the fourth region 70d and the third region 70c. The second region 70b is provided between the fifth region 70e and the third region 70c. These regions are arranged in a plane (the X-Y plane) perpendicular to the direction from the semiconductor layer 30 toward the gate electrode 10.

The source electrode 50 is electrically connected to the first region 70a. The drain electrode 60 is electrically connected to the second region 70b.

A first direction is a direction connecting the first region 70a and the second region 70b. In the example, the first direction is the X-axis direction. A second direction is a direction crossing the first direction. The second direction is a direction connecting the first region 70a and the source electrode 50. The second direction is, for example, a direction orthogonal to the first direction. The second direction is, for example, the Z-axis direction. The third region 70c, the fourth region 70d, and the fifth region 70e have a third thickness D3 along the second direction. That is, the third region 70c, the fourth region 70d, and the fifth region 70e have the same thickness.

A first thickness D1 of the first region 70a along the second direction is thinner than the third thickness D3 along the second direction. Similarly, a second thickness D2 of the second region 70b along the second direction is thinner than the third thickness D3 along the second direction.

In other words, a portion of a first portion 80a of the semiconductor layer 30 is removed as described in a manufacturing method described below. The source electrode 50 is connected to the first region 70a remaining where the portion is removed. Similarly, a portion of a second portion 80b of the semiconductor layer 30 is removed. The drain electrode 60 is connected to the second region 70b remaining where the portion is removed.

It is favorable for the difference between the third thickness D3 and the first thickness D1, i.e., a removed thickness D4 of the portion of the first portion 80a, to be 3 nanometers or more. Similarly, it is favorable for the difference between the third thickness D3 and the second thickness D2, i.e., a removed thickness D5 of the portion of the second portion 80b, to be 3 nanometers or more. It is sufficient for both the removed thickness D4 and the removed thickness D5 to be 3 nanometers or more. The removed thickness D4 and the removed thickness D5 may not always match.

The semiconductor layer 30 has a first surface 30a crossing the second direction, and a second surface 30b crossing the second direction and being opposite to the first surface 30a. The source electrode 50 is electrically connected to the portion of the first surface 30a in the first region 70a. The drain electrode 60 is electrically connected to the portion of the first surface 30a in the second region 70b. At least a portion of the gate insulating layer 20 is disposed between the gate electrode 10 and the second surface 30b. More specifically, the gate insulating layer 20 partially contacts the second surface 30b of the semiconductor layer 30. Thus, the thin film transistor 100 has a bottom-gate structure.

Here, in a thin film transistor in which a semiconductor including an oxide is used as the active layer, two openings that reach the semiconductor layer are formed by dry etching in an insulating film contacting the semiconductor layer. The source electrode and the drain electrode are inserted respectively via the two openings. Thereby, the source electrode and the drain electrode are connected to the semiconductor layer. The portions of the semiconductor layer to which the source electrode and the drain electrode are connected are called contact portions (corresponding to the first portion 80a and the second portion 80b of FIG. 1). The portion of the semiconductor layer in which the carriers flow is called a channel portion.

A portion of the semiconductor layer (a portion of the contact portions) reached by the openings recited above is damaged by dry etching. Compared to the other portions, the oxygen concentration is low for the portion of the contact portions that is damaged. That is, the semiconductor layer has different oxygen concentrations between the channel portion and the contact portions. Thereby, the electrical characteristics of the thin film transistor per channel length undesirably fluctuate.

Conversely, according to the embodiment, the portions of the contact portions damaged by the formation of the openings are removed. Thereby, the oxygen concentrations of the contact portions are substantially the same as the oxygen concentration of the channel portion. Thereby, the fluctuation of the electrical characteristics of the thin film transistor per channel length can be suppressed. A thin film transistor that has stable characteristics can be provided. The concentration of oxygen included in the first region 70a is, for example, not less than 90% and not more than 110% of the concentration of oxygen included in the third region 70c. The concentration of oxygen included in the second region 70b is, for example, not less than 90% and not more than 110% of the concentration of oxygen included in the third region 70c.

For example, the embodiment is favorable when forming a TFT (thin film transistor) having a short channel length inside an interconnect layer of an LSI (Large Scale Integration) substrate. In the example, a channel length Lc corresponds to a distance L between the first region 70a and the second region 70b. It is favorable for the distance L to be 2 micrometers or less.

In FIG. 2, a gate electrode film that is used to form the gate electrode 10 is formed as shown in FIG. 3A (step S1). For example, DC magnetron sputtering is used to form the gate electrode film. In such a case, the formation is implemented in an Ar atmosphere. In such a case, the material of the gate electrode film is, for example, W, Mo, Ta, Ti, Al, AlNd, Cu, etc. DC reactive magnetron sputtering may be used to form the gate electrode film. An Ar/N₂ atmosphere is used in the case where TaN or TiN is used. An Ar/O₂ atmosphere is used in the case where ITO or IZO is used.

The gate electrode 10 is formed by patterning the gate electrode film (step S2). The patterning includes, for example, reactive ion etching. In such a case, the material of the gate electrode 10 is, for example, W, Mo, Ta, Ti, Al, AlNd, etc. The patterning of the gate electrode 10 may include acid-solution wet etching. In such a case, the material of the gate electrode 10 is, for example, W, Mo, Ta, Ti, Al, AlNd, Cu, etc.

As shown in FIG. 3B, the gate insulating layer 20 is formed on the gate electrode 10 (step S3). PECVD (Plasma Enhanced Chemical Vapor Deposition) is used to form the gate insulating layer 20. In such a case, the material of the gate insulating layer 20 is, for example, silicon oxide, silicon nitride, silicon oxynitride, TEOS, etc. RF reactive magnetron sputtering may be used to form the gate insulating layer 20. In such a case, the formation is implemented in an Ar/O₂ atmosphere. In such a case, the material of the gate insulating layer 20 is, for example, silicon oxide, silicon nitride, silicon oxynitride, aluminum oxide, tantalum oxide, hafnium oxide, zirconium oxide, titanium oxide, etc. Anodic oxidation may be used to form the gate insulating layer 20. In such a case, the material of the gate insulating layer 20 is, for example, aluminum oxide, tantalum oxide, hafnium oxide, zirconium oxide, titanium oxide, etc. ALD (Atomic Layer Deposition) may be used to form the gate insulating layer 20. In such a case, the material of the gate insulating layer 20 is, for example, silicon oxide, silicon nitride, silicon oxynitride, aluminum oxide, tantalum oxide, hafnium oxide, zirconium oxide, etc.

Heat treatment is performed (step S4). For example, at least one of a clean oven or a quartz furnace is used in the heat treatment. In such a case, the temperature in the N₂ atmosphere is 200° C. to 600° C., and favorably 350° C. to 500° C.

A semiconductor film 30f that is used to form the semiconductor layer 30 is formed as shown in FIG. 3C (step S5). DC reactive magnetron sputtering is used to form the semiconductor film 30f. In such a case, the formation is implemented in an Ar/O₂ atmosphere or an Ar/O₂/N₂ atmosphere. That is, in this process, the semiconductor film 30f is formed to include an oxide and include the first portion 80a and the second portion 80b separated from the first portion 80a.

The semiconductor film 30f is patterned (patterning) (step S6). For example, the patterning of the semiconductor film 30f includes acid-solution wet etching. The patterning of the semiconductor film 30f may include reactive ion etching.

Heat treatment is performed (step S7). For example, at least one of a clean oven or a quartz furnace is used in the heat treatment. In such a case, the temperature in the N₂/O₂ atmosphere is 200° C. to 600° C., and favorably 300° C. to 500° C.

An inter-layer insulating film 40f that is used to form the inter-layer insulating layer 40 is formed as shown in FIG. 3D (step S8). For example, PECVD is used to form the inter-layer insulating film 40f. In such a case, the material of the inter-layer insulating film 40f is, for example, silicon oxide, silicon nitride, silicon oxynitride, TEOS, etc. RF reactive magnetron sputtering may be used to form the inter-layer insulating film 40f. In such a case, the formation is implemented in an Ar/O₂ atmosphere. The material of the inter-layer insulating film 40f is, for example, silicon oxide, silicon nitride, silicon oxynitride, aluminum oxide, tantalum oxide, hafnium oxide, zirconium oxide, titanium oxide, etc. Anodic oxidation may be used to form the inter-layer insulating film 40f. In such a case, the material of the inter-layer insulating film 40f is, for example, aluminum oxide, tantalum oxide, hafnium oxide, zirconium oxide, titanium oxide, etc. That is, in this process, the inter-layer insulating film 40f is formed on the semiconductor layer 30.

Heat treatment is performed (step S9). For example, at least one of a clean oven or a quartz furnace is used in the heat treatment. In such a case, the heat treatment is implemented in a N₂ atmosphere. The heat treatment may be implemented in a N₂/H₂ atmosphere. The heat treatment may be implemented in a N₂/O₂ atmosphere (O₂≧20%). The temperature is 200° C. to 600° C., and favorably 300° C. to 500° C.

As shown in FIG. 3E, openings are formed in the inter-layer insulating film 40f (step S10). That is, in this process, a first opening 40a that reaches the first portion 80a and a second opening 40b that reaches the second portion 80b are formed in the inter-layer insulating film 40f by dry etching. Specifically, reactive ion etching (RIE) which is an example of dry etching is used. CF₄ is used as the etching gas in this process (step S10). In such a case, the oxygen concentration of the front surface portion of the first portion 80a decreases. Also, the oxygen concentration of the front surface portion of the second portion 80b decreases.

As shown in FIG. 3F, a portion of the semiconductor film 30f is removed (step S11). Recesses are formed. Thereby, the semiconductor layer 30 is formed. By wet etching in this process, a portion (a first removed portion 33a) of the first portion 80a is removed via the first opening 40a; and a portion (a second removed portion 33b) of the second portion 80b is removed via the second opening 40b. Specifically, acid-solution wet etching which is an example of wet etching is used. The oxygen concentration of the first removed portion 33a is lower than the oxygen concentration of the first region 70a. Similarly, the oxygen concentration of the second removed portion 33b is lower than the oxygen concentration of the second region 70b. For example, the oxygen concentration in the first region 70a remaining where the first removed portion 33a is removed and the oxygen concentration in the second region 70b remaining where the second removed portion 33b is removed are the same as or nearly the same as the oxygen concentration of the other regions of the semiconductor layer 30.

At least one of Cl₂, BCl₃, or Ar may be used as the etching gas in step S10 recited above. In such a case, the oxygen concentration of the front surface portion of the first portion 80a does not decrease. To this end, the process of removing the low oxygen concentration layer by the wet etching described in step S11 can be omitted; and the first region 70a and the second region 70b have substantially the same oxygen concentration as the other regions of the semiconductor layer 30.

In the description recited above, it is favorable for the thickness of the first removed portion 33a to be 3 nanometers or more. Similarly, it is favorable for the thickness of the second removed portion 33b to be 3 nanometers or more.

A conductive film that is used to form the source electrode 50 and the drain electrode 60 is formed (step S12). For example, the conductive film is filled into the recesses that are formed. For example, DC magnetron sputtering may be used to form the conductive film. In such a case, the formation is implemented in an Ar atmosphere. The material of the conductive film is, for example, Ti, Mo, Al, Cu, Ta, or W. DC reactive magnetron sputtering may be used to form the conductive film. In such a case, the formation is implemented in an Ar/N₂ atmosphere. The material of the conductive film is, for example, TiN, TaN, or MoN. An Ar/O₂ atmosphere is used in the case where ITO, IZO, or InGaZnO is used. An Ar/O₂/N₂ atmosphere is used in the case where InGaZnO:N is used.

The source electrode 50 and the drain electrode 60 are formed by patterning the conductive film (step S13). The patterning may include reactive ion etching. The patterning may include acid-solution wet etching. Thereby, the source electrode 50 is connected to the first region 70a remaining where the first removed portion 33a is removed; and the drain electrode 60 is connected to the second region 70b remaining where the second removed portion 33b is removed. Thus, the inter-layer insulating layer 40 is provided between the semiconductor layer 30 and the source electrode 50 and between the semiconductor layer 30 and the drain electrode 60. The inter-layer insulating layer 40 has the first opening 40a that exposes the first region 70a and the second opening 40b that exposes the second region 70b. A portion of the source electrode 50 extends inside the first opening 40a and is electrically connected to the first region 70a via the first opening 40a. A portion of the drain electrode 60 extends inside the second opening 40b and is electrically connected to the second region 70b via the second opening 40b.

The state in which the source electrode 50 and the drain electrode 60 are connected to the semiconductor layer 30 is shown in FIG. 4. The channel length Lc is the length along the first direction (the X-axis direction) of a gate electrode 11. In such a case, it is favorable for the channel length Lc to be 2 micrometers or less. It is favorable for the distance L between the first region 70a and the second region 70b to be 2 micrometers or less.

Heat treatment is performed (step S14). For example, at least one of a clean oven or a quartz furnace is used in the heat treatment. In such a case, the heat treatment is implemented in a N₂ atmosphere. The heat treatment may be implemented in a N₂/H₂ atmosphere. The heat treatment may be implemented in a N₂/O₂ atmosphere (O₂≧20%). The temperature is 200° C. to 600° C., and favorably 250° C. to 350° C.

According to the embodiment, the portions (e.g., the first removed portion 33a and the second removed portion 33b) of the contact portions damaged by the formation of the openings are removed. The oxygen concentrations of the contact portions having portions removed are substantially the same as the oxygen concentrations of the other portions. Thereby, the fluctuation of the electrical characteristics of the thin film transistor per channel length can be suppressed. A thin film transistor that has stable characteristics can be provided.

There is a reference example in which the source electrode and the drain electrode contact the upper surface and end surface (side surface) of the semiconductor layer. Thus, the characteristics become unstable easily when the source electrode and the drain electrode contact the end surface (the side surface) of the semiconductor layer. Conversely, according to the embodiment, the source electrode and the drain electrode contact the upper surface of the semiconductor layer and do not contact the end surface (the side surface) of the semiconductor layer. Therefore, the characteristics can be stabilized.

### Second Embodiment

FIG. 5 is a schematic cross-sectional view illustrating a thin film transistor according to a second embodiment.

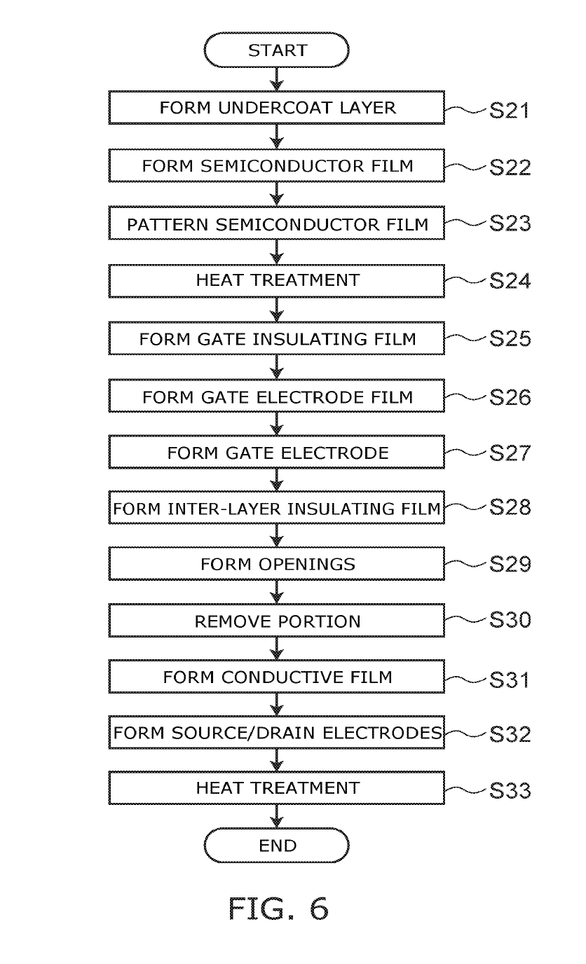

FIG. 6 is a flowchart illustrating a method for manufacturing the thin film transistor according to the second embodiment.

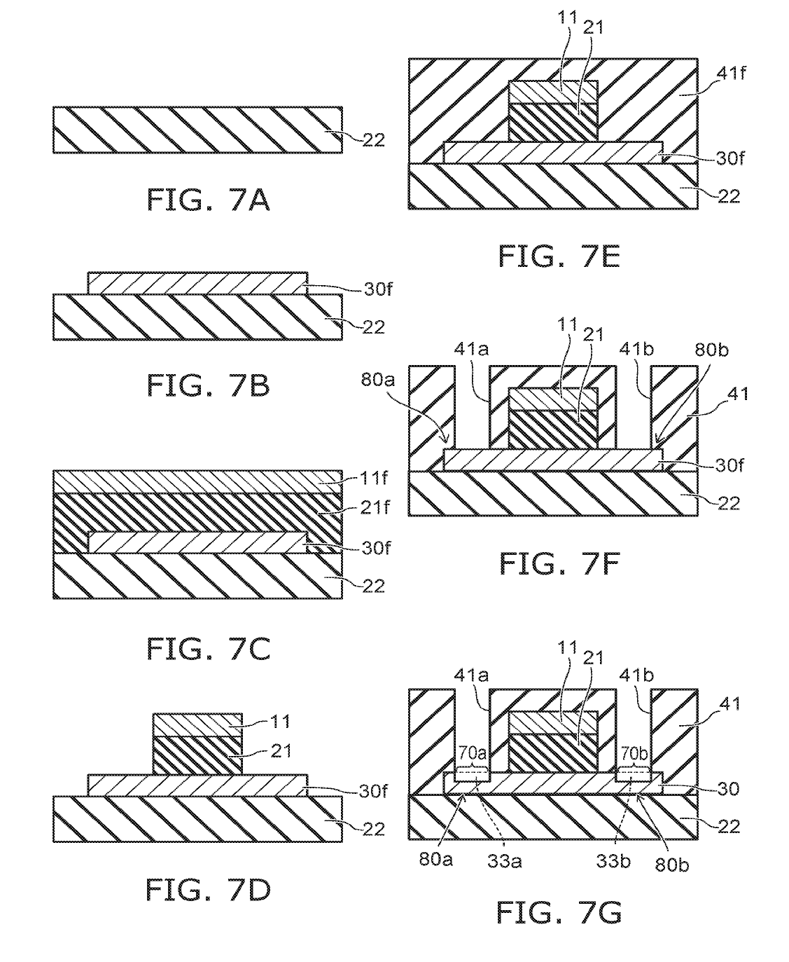

FIG. 7A to FIG. 7G are schematic cross-sectional views in order of the processes, illustrating the method for manufacturing the thin film transistor according to the second embodiment.

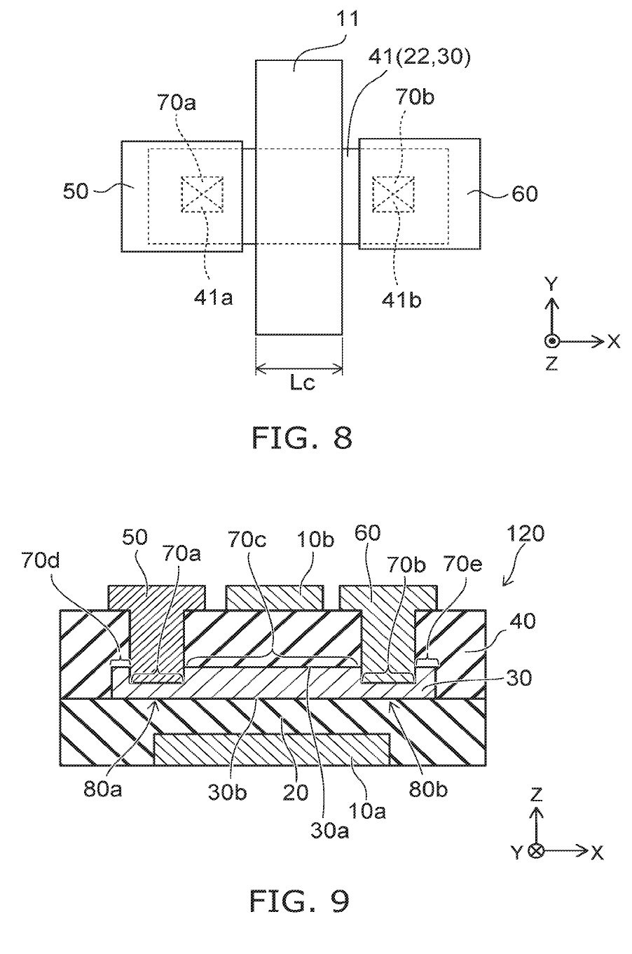

FIG. 8 is a top view of the thin film transistor according to the second embodiment.

An example of the structure of the thin film transistor 110 having a top-gate structure and a method for manufacturing the thin film transistor 110 are described in the embodiment.

As shown in FIG. 5, the thin film transistor 110 according to the embodiment includes the gate electrode 11, a gate insulating layer 21, an undercoat layer 22, the semiconductor layer 30, an inter-layer insulating layer 41, the source electrode 50, and the drain electrode 60.

The undercoat layer 22 includes, for example, one of silicon oxide, silicon nitride, silicon oxynitride, TEOS, or aluminum oxide. The undercoat layer 22 may include a mixture of these materials or a stacked structure of films of these materials. In the case where the stacked film is used, the silicon oxide and the silicon oxynitride are disposed on the upper side of the silicon nitride. The TEOS is disposed on the lower side of the silicon nitride.

The semiconductor layer 30 has a first surface 30a that crosses the second direction, and a second surface 30b that crosses the second direction and is opposite to the first surface 30a. The source electrode 50 is electrically connected to the portion of the first surface 30a in the first region 70a. The drain electrode 60 is electrically connected to the portion of the first surface 30a in the second region 70b. The gate insulating layer 21 is disposed between the gate electrode 11 and the first surface 30a. More specifically, the gate insulating layer 21 partially contacts the second surface 30b of the semiconductor layer 30. In other words, the thin film transistor 110 has a top-gate structure.

In FIG. 6, the undercoat layer 22 is formed as shown in FIG. 7A (step S21). PECVD is used to form the undercoat layer 22. In such a case, the material of the undercoat layer 22 is, for example, silicon oxide, silicon nitride, silicon oxynitride, TEOS, etc. RF reactive magnetron sputtering may be used to form the undercoat layer 22. In such a case, the formation is implemented in an Ar/O₂ atmosphere. The material of the undercoat layer 22 is, for example, silicon oxide, silicon nitride, silicon oxynitride, aluminum oxide, etc. Anodic oxidation may be used to form the undercoat layer 22. The material of the undercoat layer 22 is, for example, aluminum oxide, etc.

The semiconductor film 30f that is used to form the semiconductor layer 30 is formed as shown in FIG. 7B (step S22). For example, DC reactive magnetron sputtering is used to form the semiconductor film 30f. In such a case, the formation is implemented in an Ar/O₂ atmosphere or in an Ar/O₂/N₂ atmosphere. That is, in this process, the semiconductor film 30f is formed to include an oxide and include the first portion 80a and the second portion 80b separated from the first portion 80a.

Patterning of the semiconductor film 30f is performed (step S23). The patterning includes acid-solution wet etching. The patterning may include reactive ion etching.

Heat treatment is performed (step S24). For example, at least one of a clean oven or a quartz furnace is used in the heat treatment. In such a case, the temperature of the N₂/O₂ atmosphere is 200° C. to 600° C., and favorably 300° C. to 500° C.

A gate insulating film 21f that is used to form the gate insulating layer 21 is formed as shown in FIG. 7C (step S25). PECVD is used to form the gate insulating film 21f. In such a case, the material of the gate insulating film 21f is, for example, silicon oxide, silicon nitride, silicon oxynitride, TEOS, etc. RF reactive magnetron sputtering may be used to form the gate insulating film 21f. In such a case, the formation is implemented in an Ar/O₂ atmosphere. In such a case, the material of the gate insulating film 21f is, for example, silicon oxide, silicon nitride, silicon oxynitride, aluminum oxide, tantalum oxide, hafnium oxide, zirconium oxide, titanium oxide, etc. Anodic oxidation may be used to form the gate insulating film 21f. In such a case, the material of the gate insulating film 21f is, for example, aluminum oxide, tantalum oxide, hafnium oxide, zirconium oxide, titanium oxide, etc. ALD may be used to form the gate insulating film 21f. The material of the gate insulating film 21f is, for example, silicon oxide, silicon nitride, silicon oxynitride, aluminum oxide, tantalum oxide, hafnium oxide, zirconium oxide, etc.

As shown in FIG. 7C, a gate electrode film 11f that is used to form the gate electrode 11 is formed (step S26). For example, DC magnetron sputtering is used to form the gate electrode film 11f. In such a case, the formation is implemented in an Ar atmosphere. In such a case, the material of the gate electrode film 11f is, for example, W, Mo, Ta, Ti, Al, AlNd, Cu, etc. DC reactive magnetron sputtering may be used to form the gate electrode film 11f. An Ar/N₂ atmosphere is used in the case where TaN or TiN is used. An Ar/O₂ atmosphere is used in the case where ITO or IZO is used.

As shown in FIG. 7D, the gate electrode 11 is formed by patterning the gate electrode film 11f (step S27). The patterning includes reactive ion etching. In such a case, the material of the gate electrode film 11f is, for example, W, Mo, Ta, Ti, Al, AlNd, etc.

An inter-layer insulating film 41f that is used to form the inter-layer insulating layer 41 is formed as shown in FIG. 7E (step S28). For example, PECVD is used to form the inter-layer insulating film 41f. In such a case, the material of the inter-layer insulating film 41f is, for example, silicon oxide, silicon nitride, silicon oxynitride, TEOS, etc. RF reactive magnetron sputtering may be used to form the inter-layer insulating film 41f. In such a case, the formation is implemented in an Ar/O₂ atmosphere. In such a case, the material of the inter-layer insulating film 41f, for example, silicon oxide, silicon nitride, silicon oxynitride, etc. In this process, the inter-layer insulating film 41f is formed on the semiconductor film 30f.

As shown in FIG. 7F, openings are formed in the inter-layer insulating film 41f (step S29). That is, in this process, a first opening 41a that reaches the first portion 80a and a second opening 41b that reaches the second portion 80b are formed in the inter-layer insulating film 41f by dry etching. Specifically, reactive ion etching which is an example of dry etching is used. CF₄ is used as the etching gas of this process (step S29). In such a case, the oxygen concentration of the front surface portion of the first portion 80a decreases. Also, the oxygen concentration of the front surface portion of the second portion 80b decreases.

A portion of the semiconductor film 30f is removed as shown in FIG. 7G (step S30). Recesses are formed. Thereby, the semiconductor layer 30 is formed. By wet etching in this process, the first removed portion 33a which is a portion of the first portion 80a is removed via the first opening 41a; and the second removed portion 33b which is a portion of the second portion 80b is removed via the second opening 41b.

Specifically, acid-solution wet etching which is an example of wet etching is used. The oxygen concentration of the first removed portion 33a is lower than the oxygen concentration of the first region 70a. Similarly, the oxygen concentration of the second removed portion 33b is lower than the oxygen concentration of the second region 70b. That is, the first region 70a that remains where the first removed portion 33a is removed and the second region 70b that remains where the second removed portion 33b is removed have substantially the same oxygen concentration as the other regions of the semiconductor layer 30.

At least one of Cl₂, BCl₃, or Ar may be used as the etching gas in step S29 recited above. In such a case, the oxygen concentration of the front surface portion of the first portion 80a does not decrease. Therefore, the process of removing the low oxygen concentration layer by wet etching described in reference to step S30 can be omitted; and the first region 70a and the second region 70b have substantially the same oxygen concentration as the other regions of the semiconductor layer 30. A conductive film that is used to form the source electrode 50 and the drain electrode 60 is formed (step S31). For example, DC magnetron sputtering may be used to form the conductive film. In such a case, the formation is implemented in an Ar atmosphere. The material of the conductive film is, for example, Ti, Mo, Al, Cu, Ta, W, etc. DC reactive magnetron sputtering may be used to form the conductive film. In such a case, the formation is implemented in an Ar/N₂ atmosphere. The material of the conductive film is, for example, TiN, TaN, MoN, etc. An Ar/O₂ atmosphere is used in the case where ITO, IZO, or InGaZnO is used. An Ar/O₂/N₂ atmosphere is used in the case where InGaZnO:N is used.

The source electrode 50 and the drain electrode 60 are formed by patterning the conductive film (step S32). For example, reactive ion etching is used in the patterning. Acid-solution wet etching may be used in the patterning. Thereby, the source electrode 50 is connected to the first region 70a remaining where the first removed portion 33a is removed; and the drain electrode 60 is connected to the second region 70b remaining where the second removed portion 33b is removed.

The state in which the source electrode 50 and the drain electrode 60 are connected to the semiconductor layer 30 is shown in FIG. 8. In the example, the channel length Lc is the length along the first direction (the X-axis direction) of the gate electrode 11. It is favorable for the channel length Lc to be 2 micrometers or less.

Heat treatment is performed (step S33). For example, at least one of a clean oven or a quartz furnace is used in the heat treatment. In such a case, the heat treatment is implemented in a N₂ atmosphere. The heat treatment may be implemented in a N₂/H₂ atmosphere. The heat treatment may be implemented in a N₂/O₂ atmosphere (O₂≧20%). The temperature is 200° C. to 600° C., and favorably 250° C. to 350° C.

According to the embodiment, for example, a thin film transistor that has stable characteristics can be provided. Further, flexible design that corresponds to the purpose of utilization of the thin film transistor is possible due to the top-gate structure.

### Third embodiment

FIG. 9 is a schematic cross-sectional view illustrating a thin film transistor according to a third embodiment.

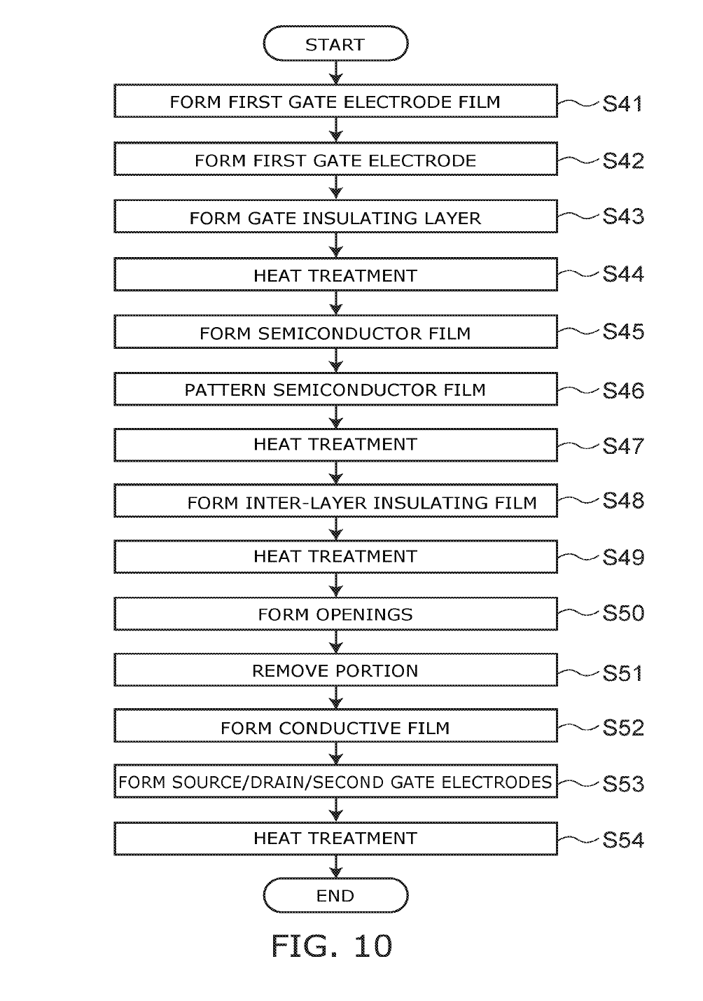

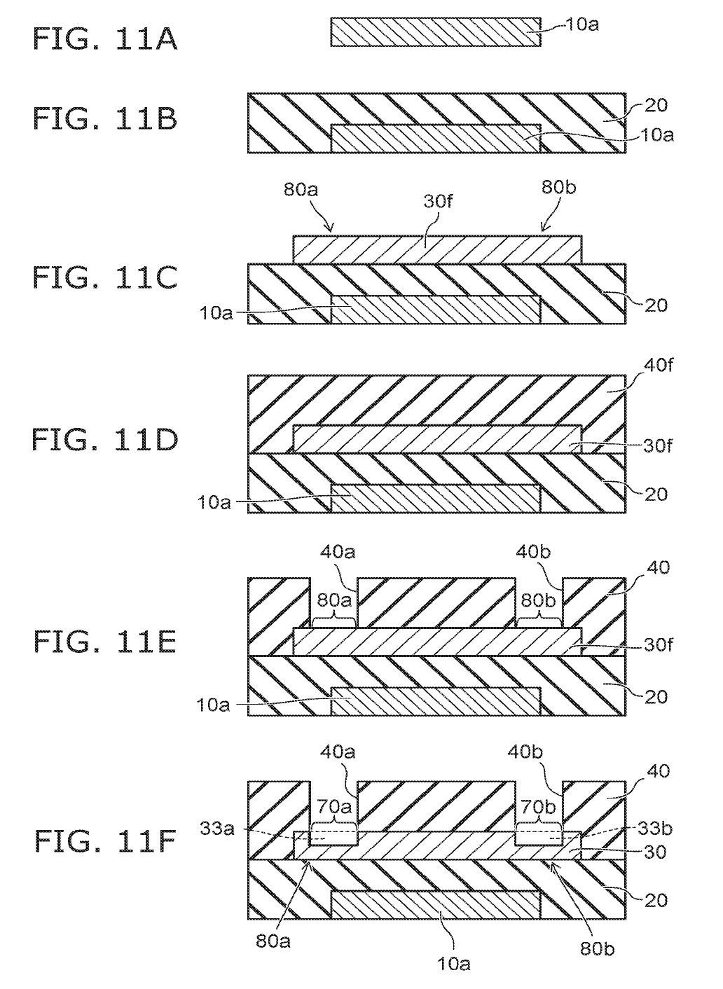

FIG. 10 is a flowchart illustrating a method for manufacturing the thin film transistor according to the third embodiment.

FIG. 11A to FIG. 11F are schematic cross-sectional views in order of the processes, illustrating the method for manufacturing the thin film transistor according to the third embodiment.

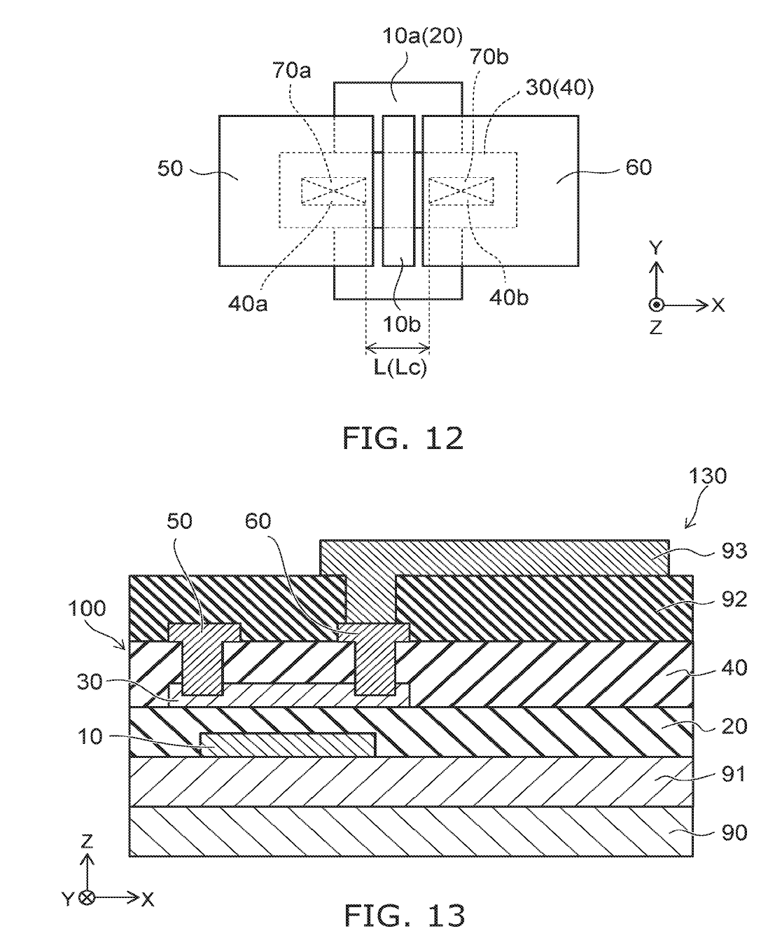

FIG. 12 is a top view of the thin film transistor according to the third embodiment.

An example of the structure of the thin film transistor 120 having a double-gate structure and a method for manufacturing the thin film transistor 120 are described in the embodiment.

As shown in FIG. 9, the thin film transistor 120 according to the embodiment includes a first gate electrode 10a, a second gate electrode 10b, the gate insulating layer 20, the semiconductor layer 30, the inter-layer insulating layer 40 (e.g., an etching stopper layer), the source electrode 50, and the drain electrode 60.

The semiconductor layer 30 has the first surface 30a that crosses the second direction, and the second surface 30b that crosses the second direction and is opposite to the first surface 30a. The source electrode 50 is electrically connected to the portion of the first surface 30a in the first region 70a. The drain electrode 60 is electrically connected to the portion of the first surface 30a in the second region 70b. The gate insulating layer 20 is disposed between the first gate electrode 10a and the second surface 30b. More specifically, the gate insulating layer 20 partially contacts the second surface 30b of the semiconductor layer 30. In other words, the first gate electrode 10a is disposed at a bottom position.

The inter-layer insulating layer 40 is disposed between the second gate electrode 10b and the first surface 30a. More specifically, the inter-layer insulating layer 40 partially contacts the first surface 30a of the semiconductor layer 30. In other words, the second gate electrode 10b is disposed at a top position.

In FIG. 10, a first gate electrode film that is used to form the first gate electrode 10a is formed as shown in FIG. 11A (step S41). For example, DC magnetron sputtering is used to form the first gate electrode film. In such a case, the formation is implemented in an Ar atmosphere. In such a case, the material of the first gate electrode film is, for example, W, Mo, Ta, Ti, Al, AlNd, Cu, etc. DC reactive magnetron sputtering may be used to form the first gate electrode film 10a. An Ar/N₂ atmosphere is used in the case where TaN or TiN is used. An Ar/O₂ atmosphere is used in the case where ITO or IZO is used.

The first gate electrode 10a is formed by patterning the first gate electrode film (step S42). Reactive ion etching is used in the patterning. In such a case, the material of the first gate electrode film is, for example, W, Mo, Ta, Ti, Al, AlNd, etc. Acid-solution wet etching may be used in the patterning. In such a case, the material of the first gate electrode film is, for example, W, Mo, Ta, Ti, Al, AlNd, Cu, etc.

As shown in FIG. 11B, the gate insulating layer 20 is formed on the first gate electrode 10a (step S43). PECVD is used to form the gate insulating layer 20. In such a case, the material of the gate insulating layer 20 is, for example, silicon oxide, silicon nitride, silicon oxynitride, TEOS, etc. RF reactive magnetron sputtering may be used to form the gate insulating layer 20. In such a case, the formation is implemented in an Ar/O₂ atmosphere. In such a case, the material of the gate insulating layer 20 is, for example, silicon oxide, silicon nitride, silicon oxynitride, aluminum oxide, tantalum oxide, hafnium oxide, zirconium oxide, titanium oxide, etc. Anodic oxidation may be used to form the gate insulating layer 20. In such a case, the material of the gate insulating layer 20 is, for example, aluminum oxide, tantalum oxide, hafnium oxide, zirconium oxide, titanium oxide, etc. ALD may be used to form the gate insulating layer 20. The material of the gate insulating layer is, for example, silicon oxide, silicon nitride, silicon oxynitride, aluminum oxide, tantalum oxide, hafnium oxide, zirconium oxide, etc.

Heat treatment is performed (step S44). For example, at least one of a clean oven or a quartz furnace is used in the heat treatment. In such a case, the temperature of the N₂ atmosphere is 200° C. to 600° C., and favorably 350° C. to 500° C.

As shown in FIG. 11C, the semiconductor film 30f that is used to form the semiconductor layer 30 is formed (step S45). For example, DC reactive magnetron sputtering is used to form the semiconductor film 30f. In such a case, the formation is implemented in an Ar/O₂ atmosphere or an Ar/O₂/N₂ atmosphere. That is, in this process, the semiconductor film 30f is formed to include an oxide and include the first portion 80a and the second portion 80b separated from the first portion 80a.

The semiconductor film 30f is patterned (patterning) (step S46). For example, acid-solution wet etching is used in the patterning of the semiconductor film 30f. Reactive ion etching may be used in the patterning of the semiconductor film 30f.

Heat treatment is performed (step S47). For example, at least one of a clean oven or a quartz furnace is used in the heat treatment. In such a case, the temperature of the N₂/O₂ atmosphere is 200° C. to 600° C., and favorably 300° C. to 500° C.

The inter-layer insulating film 40f that is used to form the inter-layer insulating layer 40 is formed as shown in FIG. 11D (step S48). For example, PECVD is used to form the inter-layer insulating film 40f. In such a case, the material of the inter-layer insulating film 40f is, for example, silicon oxide, silicon nitride, silicon oxynitride, TEOS, etc. RF reactive magnetron sputtering may be used to form the inter-layer insulating film 40f. In such a case, the formation is implemented in an Ar/O₂ atmosphere. In such a case, the material of the inter-layer insulating film 40f is, for example, silicon oxide, silicon nitride, silicon oxynitride, aluminum oxide, tantalum oxide, hafnium oxide, zirconium oxide, titanium oxide, etc. Anodic oxidation may be used to form the inter-layer insulating film 40f. In such a case, the material of the inter-layer insulating film 40f is, for example, aluminum oxide, tantalum oxide, hafnium oxide, zirconium oxide, titanium oxide, etc. That is, in this process, the inter-layer insulating film 40f is formed on the semiconductor layer 30. ALD may be used to form the gate insulating layer 20. The material of the gate insulating layer 20 is, for example, silicon oxide, silicon nitride, silicon oxynitride, aluminum oxide, tantalum oxide, hafnium oxide, zirconium oxide, etc.

Heat treatment is performed (step S49). For example, at least one of a clean oven or a quartz furnace is used in the heat treatment. In such a case, the heat treatment is implemented in a N₂ atmosphere. The heat treatment may be implemented in a N₂/H₂ atmosphere. The heat treatment may be implemented in a N₂/O₂ atmosphere (O₂≧20%). The temperature is 200° C. to 600° C., and favorably 300° C. to 500° C.

As shown in FIG. 11E, openings are formed in the inter-layer insulating film 40f (step S50). That is, by dry etching in this process, the first opening 40a that reaches the first portion 80a and the second opening 40b that reaches the second portion 80b are formed in the inter-layer insulating film 40f. Specifically, reactive ion etching which is an example of dry etching is used.

CF₄ is used as the etching gas in this process (step S50). In such a case, the oxygen concentration of the front surface portion of the first portion 80a decreases. Also, the oxygen concentration of the front surface portion of the second portion 80b decreases.

A portion of the semiconductor film 30f is removed as shown in FIG. 11F (step S51). That is, by wet etching in this process, the first removed portion 33a of a portion of the first portion 80a is removed via the first opening 40a; and the second removed portion 33b of a portion of the second portion 80b is removed via the second opening 40b. Specifically, acid-solution wet etching which is an example of wet etching is used. The oxygen concentration of the first removed portion 33a is lower than the oxygen concentration of the first region 70a. The oxygen concentration of the second removed portion 33b is lower than the oxygen concentration of the second region 70b. After the removed portions are removed, the first region 70a that remains where the first removed portion 33a is removed and the second region 70b that remains where the second removed portion 33b is removed have substantially the same oxygen concentration as the other regions of the semiconductor layer 30.

At least one of C1₂, BCl₃, or Ar may be used as the etching gas in step S50 recited above. In such a case, the oxygen concentration of the front surface portion of the first portion 80a does not decrease. Therefore, the process of removing the low oxygen concentration layer due to the wet etching described in reference to step S51 can be omitted; and the first region 70a and the second region 70b have substantially the same oxygen concentration as the other regions of the semiconductor layer 30.

A conductive film that is used to form the source electrode 50, the drain electrode 60, and the second gate electrode 10b is formed (step S52). For example, DC magnetron sputtering may be used to form the conductive film. In such a case, the formation is implemented in an Ar atmosphere. The material of the conductive film is, for example, Ti, Mo, Al, Cu, Ta, W, etc. DC reactive magnetron sputtering may be used to form the conductive film. In such a case, the formation is implemented in an Ar/N₂ atmosphere. In such a case, the material of the conductive film is, for example, TiN, TaN, MoN, etc. An Ar/O₂ atmosphere is used in the case where ITO, IZO, or InGaZnO is used. An Ar/O₂/N₂ atmosphere is used in the case where InGaZnO:N is used.

The source electrode 50, the drain electrode 60, and the second gate electrode 10b (the top) are formed by patterning the conductive film (step S53). In this process, the source electrode 50 is connected to the first region 70a remaining where the first removed portion 33a is removed; and the drain electrode 60 is connected to the second region 70b remaining where the second removed portion 33b is removed.

The state in which the source electrode 50 and the drain electrode 60 are connected to the semiconductor layer 30 is shown in FIG. 12. In such a case, the distance L between the first region 70a and the second region 70b substantially corresponds to the channel length Lc. It is favorable for the length L to be 2 micrometers or less.

Heat treatment is performed (step S54). For example, at least one of a clean oven or a quartz furnace is used in the heat treatment. In such a case, the heat treatment is implemented in a N₂ atmosphere. The heat treatment may be implemented in a N₂/H₂ atmosphere. The heat treatment may be implemented in a N₂/O₂ atmosphere (O₂≧20%). The temperature is 200° C. to 600° C., and favorably 250° C. to 350° C.

According to the embodiment, a thin film transistor that has stable characteristics can be provided. Further, flexible design that corresponds to the purpose of utilization of the thin film transistor is possible due to the double-gate structure.

### Fourth Embodiment

The embodiment relates to a display device.

FIG. 13 is a schematic cross-sectional view illustrating a display device according to a fourth embodiment.

The display device 130 according to the embodiment includes a thin film transistor, a substrate 90, an undercoat layer 91, a passivation layer 92, and a pixel electrode 93. In the example, the thin film transistor 100 is used as the thin film transistor. The thin film transistors and modifications of the thin film transistors according to the embodiments recited above may be used as the thin film transistor. The display device 130 is, for example, a liquid crystal display device or an organic EL display device. In the example, the pixel electrode 93 is electrically connected to the drain electrode 60. The pixel electrode 93 may be electrically connected to the source electrode 50. In other words, the pixel electrode 93 is electrically connected to one of the source electrode 50 or the drain electrode 60.

In the case of the bottom-emission type, the pixel electrode 93 includes, for example, ITO, IZO, InGaZnO, etc. In the case of the top-emission type, Al is added to the lower layer of the pixel electrode 93 as a reflecting electrode.

The passivation layer 92 includes, for example, silicon oxide, silicon nitride, silicon oxynitride, TEOS, aluminum oxide, tantalum oxide, hafnium oxide, zirconium oxide, titanium oxide, etc. The passivation layer 92 may include a mixture of these materials or a stacked structure of films of these materials.

PECVD is used to form the passivation layer 92. The material of the passivation layer 92 is, for example, silicon oxide, silicon nitride, silicon oxynitride, TEOS, etc. RF reactive magnetron sputtering may be used to form the passivation layer 92. In such a case, the formation is implemented in an Ar/O₂ atmosphere. In such a case, the material of the passivation layer 92 is, for example, silicon oxide, silicon nitride, silicon oxynitride, aluminum oxide, tantalum oxide, hafnium oxide, zirconium oxide, titanium oxide, etc.

For example, reactive ion etching is used in the patterning (the formation of the openings) of the passivation layer 92. For example, DC reactive magnetron sputtering is used to form the pixel electrode 93. In such a case, the formation is implemented in an Ar/O₂ atmosphere. For example, acid-solution wet etching is used in the patterning of the pixel electrode 93.

### Fifth Embodiment

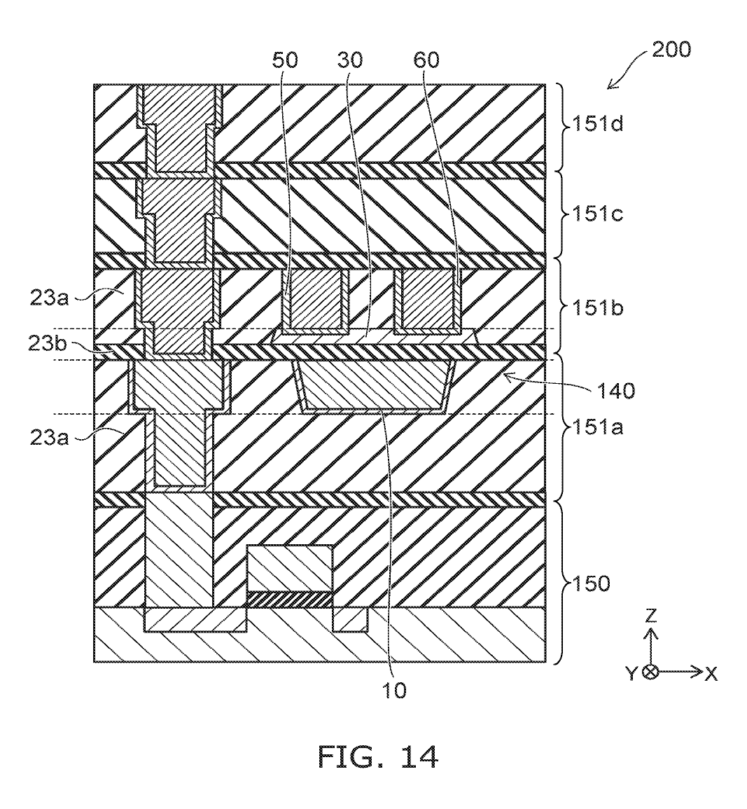

FIG. 14 is a schematic view illustrating a semiconductor device according to a fifth embodiment.

The semiconductor device 200 according to the embodiment includes a semiconductor circuit 150, interconnect layers 151a to 151d, and a thin film transistor 140. The thin film transistor 140 is formed inside the interconnect layers of the semiconductor circuit 150. In the example, the thin film transistor 140 is formed in the first interconnect layer 151a. The thin film transistor 140 may be formed in the Nth interconnect layers 151b to 151d. The thin film transistors and modifications of the thin film transistors according to the embodiments recited above are used as the thin film transistor 140.

For example, Cu or TaN that is inside the interconnect layers is used as the gate electrode 10. SiOₓ or SiNₓ that is inside the interconnect layers is used as an insulating layer 23b and an insulating layer 23a of the gate electrode 10. The insulating layer 23a is, for example, SiOₓ. The insulating layer 23b is, for example, SiNₓ. Thus, the thin film transistor of the embodiment is applicable to a semiconductor device as well.

In the description recited above, the thin film transistor 140 includes the semiconductor layer 30. The source electrode and the drain electrode 60 are connected to the semiconductor layer 30. In the example, the gate electrode 10 is interconnected in the planar direction inside the first interconnect layer 151a. In the example, interconnects are not provided in the interconnect layers (i.e., the Nth interconnect layers 151c and 151d) above the semiconductor layer 30.

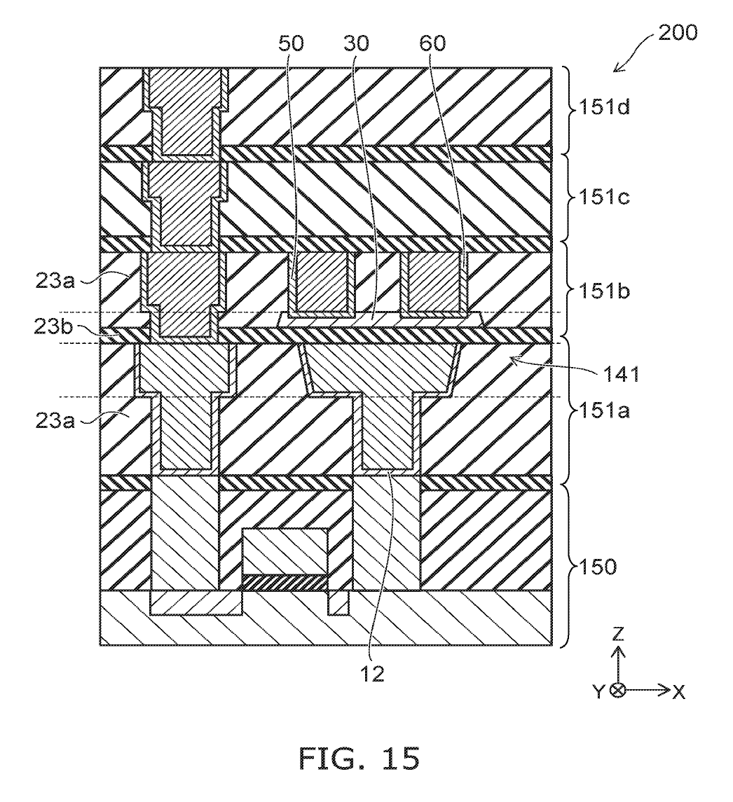

FIG. 15 is a schematic view showing another semiconductor device according to the fifth embodiment.

The semiconductor device 200 according to the embodiment includes the semiconductor circuit 150, the interconnect layers 151a to 151d, and a thin film transistor 141. The thin film transistor 141 is formed inside the interconnect layers of the semiconductor circuit 150. In the example, the thin film transistor 141 is formed in the first interconnect layer 151a. The thin film transistor 141 may be formed in the Nth interconnect layers 151b to 151d. The thin film transistors and modifications of the thin film transistors according to the embodiments recited above are used as the thin film transistor 141.

For example, Cu or TaN that is inside the interconnect layers is used as a gate electrode 12. SiOₓ or SiNₓ that is inside the interconnect layers is used as the insulating layer 23b and the insulating layer 23a of the gate electrode 12. The insulating layer 23a is, for example, SiOₓ. The insulating layer 23b is, for example, SiN_{X}.

In the example, the gate electrode 12 is directly connected to the semiconductor circuit 150 of the foundation. The gate electrode 12 is electrically connected to the semiconductor circuit 150. The thin film transistor 141 includes the semiconductor layer 30. The source electrode 50 and the drain electrode 60 are connected to the semiconductor layer 30. In the example, interconnects are not provided in the interconnect layers (i.e., the Nth interconnect layers 151c and 151d) above the semiconductor layer 30.

According to the embodiments, a thin film transistor, a semiconductor device, and a method for manufacturing the thin film transistor having stable characteristics are provided. Hereinabove, embodiments of the invention are described with reference to specific examples.

However, the embodiments of the invention are not limited to these specific examples. For example, one skilled in the art may similarly practice the invention by appropriately selecting specific configurations of components such as semiconductor layers, source electrodes, and drain electrodes etc., from known art; and such practice is included in the scope of the invention to the extent that similar effects are obtained.

Further, any two or more components of the specific examples may be combined within the extent of technical feasibility and are included in the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A thin film transistor, comprising:
a semiconductor layer including a first region, a second region, a third region, a fourth region, and a fifth region, the third region being provided between the first region and the second region, the first region being disposed between the fourth region and the third region, the second region being disposed between the fifth region and the third region, the semiconductor layer including an oxide;
a source electrode electrically connected to the first region; and
a drain electrode electrically connected to the second region,
a first thickness of the first region along a second direction being thinner than a third thickness along the second direction of each of the third region, the fourth region, and the fifth region, the second direction crossing a first direction and connecting the first region and the source electrode, the first direction connecting the first region and the second region,
a second thickness of the second region along the second direction being thinner than the third thickness.

2. The thin film transistor according to claim 1, wherein
a difference between the third thickness and the first thickness is 3 nanometers or more, and
a difference between the third thickness and the second thickness is 3 nanometers or more.

3. The thin film transistor according to claim 1, further comprising:
a gate electrode; and
a gate insulating layer provided between the third region and the gate electrode.

4. The thin film transistor according to claim 3, wherein
the semiconductor layer has:
a first surface crossing the second direction; and
a second surface crossing the second direction and being opposite to the first surface,
the source electrode is electrically connected to a portion of the first surface in the first region,
the drain electrode is electrically connected to a portion of the first surface in the second region, and
the gate insulating layer is disposed between the gate electrode and the second surface.

5. The thin film transistor according to claim 4, wherein a distance between the first region and the second region is 2 micrometers or less.

6. The thin film transistor according to claim 3, wherein
the semiconductor layer has:
a first surface crossing the second direction; and
a second surface crossing the second direction and being opposite to the first surface,
the source electrode is electrically connected to a portion of the first surface in the first region,
the drain electrode is electrically connected to a portion of the first surface in the second region, and
the gate insulating layer is disposed between the gate electrode and the first surface.

7. The thin film transistor according to claim 6, wherein a length of the gate electrode along the first direction is 2 micrometers or less.

8. The thin film transistor according to claim 1, further comprising:
a first gate electrode;
a second gate electrode;
a first gate insulating layer; and
a second gate insulating layer,
the semiconductor layer having
a first surface crossing the second direction, and
a second surface crossing the second direction and being opposite to the first surface,
the source electrode being electrically connected to a portion of the first surface in the first region,
the drain electrode being electrically connected to a portion of the first surface in the second region,
the first gate insulating layer being disposed between the first gate electrode and the second surface,
the second gate insulating layer being disposed between the second gate electrode and the first surface.

9. The thin film transistor according to claim 1, further comprising an inter-layer insulating layer provided between the semiconductor layer and the source electrode and between the semiconductor layer and the drain electrode,
the inter-layer insulating layer having a first opening and a second opening, the first opening exposing the first region, the second opening exposing the second region,
a portion of the source electrode extending inside the first opening and being electrically connected to the first region via the first opening,
a portion of the drain electrode extending inside the second opening and being electrically connected to the second region via the second opening.

10. The thin film transistor according to claim 1, wherein the source electrode and the drain electrode do not contact an end portion in the first direction of the semiconductor layer.

11. The thin film transistor according to claim 1, wherein the semiconductor layer includes an oxide of at least one of In, Ga, or Zn.

12. The thin film transistor according to claim 1, wherein
a concentration of oxygen included in the first region is not less than 90% and not more than 110% of a concentration of oxygen included in the third region, and
a concentration of oxygen included in the second region is not less than 90% and not more than 110% of the concentration of oxygen included in the third region.

13. A semiconductor device, comprising:
a semiconductor circuit;
an interconnect layer including an interconnect, the interconnect being connected to the semiconductor circuit; and
a thin film transistor including a semiconductor layer, a source electrode, and a drain electrode,
the semiconductor layer including a first region, a second region, a third region, a fourth region, and a fifth region, the third region being provided between the first region and the second region, the first region being disposed between the fourth region and the third region, the second region being disposed between the fifth region and the third region, the semiconductor layer including an oxide,
the source electrode being electrically connected to the first region,
the drain electrode being electrically connected to the second region,
a first thickness of the first region along a second direction being thinner than a third thickness along the second direction of each of the third region, the fourth region, and the fifth region, the second direction crossing a first direction and connecting the first region and the source electrode, the first direction connecting the first region and the second region,
a second thickness of the second region along the second direction being thinner than the third thickness, and
the thin film transistor being provided inside the interconnect layer.

14. The semiconductor device according to claim 13, wherein
the thin film transistor further includes:
a gate electrode; and
a gate insulating layer provided between the third region and the gate electrode,
the gate electrode is electrically connected to the semiconductor circuit.

15. A method for manufacturing a thin film transistor, comprising:
forming a semiconductor film including a first portion and a second portion, the second portion being separated from the first portion, the semiconductor film including an oxide;
forming an inter-layer insulating film on the semiconductor film;
forming a first opening and a second opening in the inter-layer insulating film by dry etching, the first opening reaching the first portion, the second opening reaching the second portion;
removing a first removed portion via the first opening and a second removed portion via the second opening by wet etching, the first removed portion being a portion of the first portion, the second removed portion being a portion of the second portion; and
connecting a source electrode to a first region remaining where the first removed portion is removed, and connecting a drain electrode to a second region remaining where the second removed portion is removed.

16. The method according to claim 15, wherein the forming of the first opening and the second opening includes reducing an oxygen concentration of a front surface portion of the first portion and reducing an oxygen concentration of a front surface portion of the second portion.

17. The method according to claim 15, wherein
an oxygen concentration of the first removed portion is lower than an oxygen concentration of the first region, and
an oxygen concentration of the second removed portion is lower than an oxygen concentration of the second region.

18. The method according to claim 15, wherein a thickness of the first removed portion and a thickness of the second removed portion each are 3 nanometers or more.

19. The method according to claim 15, wherein a distance between the first region and the second region is 2 micrometers or less.
